(19) United States
(12) Patent Application Publication
(10) Pub. No.: US 2026/0322445 A1
(43) Pub. Date: Oct. 15, 2026

(54) SYSTEM AND METHOD FOR TRANSPORTING CSI FRAMES

(71) Applicant: ASSA ABLOY AB, Stockholm (SE)

(72) Inventors: Kapil Sachdeva, Round Rock, TX (US); Sylvain Jacques Prevost, Austin, TX (US)

(21) Appl. No.: 19/102,625

(22) PCT Filed: Aug. 9, 2023
(86) PCT No.: PCT/EP2023/072105

§ 371 Date: Feb. 10, 2025

Related U.S. Application Data
(60) Provisional application No. 63/371,300, filed on Aug. 12, 2022.

(51) Int. Cl. H04B 7/06

(52) U.S. Cl. CPC H04B 7/0626

(57) ABSTRACT

A wi-fi sensing systems and techniques using receiving devices with two radio chains are described herein. The receiving devices may utilize the first radio chain to receive messages from a transmitter in a first wireless communication network and may generate environment characterization information based on those received messages. The receiving devices may utilize the second radio chain to transmit the environment characterization information to a host device using a second wireless communication network.

### CROSS-REFERENCE TO RELATED APPLICATION

This application claims the benefit of priority to U.S. Provisional Patent Application Ser. No. 63/371,300 filed Aug. 12, 2022, the contents of which are incorporated herein by reference in entirety.

### TECHNICAL FIELD

The present disclosure generally relates to wi-fi sensing for environment characterization and communication techniques for the environment characterization information.

### BACKGROUND

Wi-fi sensing refers to using wi-fi signals communicated between two devices, such as a transmitter and receiver, to characterize the environment in which the communication devices reside. Objects in the environment, such as human beings, trees, pets, etc., can cause reflections and distortions of the electromagnetic wi-fi signals. For example, a human being in a room can impact the travel path of a wi-fi signal. The impact of the objects to the environment can be characterized based on properties of the received wi-fi signals to detect possible patterns in the properties. These patterns can be used for different applications. However, conventional wi-fi sensing systems do not include efficient and low-cost techniques for collecting the characterization information.

### SUMMARY

This disclosure describes a device for wi-fi sensing. The device comprises a first radio chain to receive messages from a transmitter associated with a first wireless communication network, wherein the device to generate channel state information (CSI) frames based on the received messages; and a second radio chain to transmit the CSI frames to a host device using a second wireless communication network.

This disclosure also describes a method for wi-fi sensing. The method comprising: receiving messages from a transmitter associated with a first wireless communication network; generating CSI frames based on the received messages; and transmitting the CSI frames to a host device using a second wireless communication network.

This disclosure further describes a wi-fi sensing system. The system comprises a transmitter to transmit messages; a host device; and a receiver to receive the messages from the transmitter using a first wireless communication network, to generate CSI frames based on the received messages, and to transmit the CSI frames to the host device using a second wireless communication network.

### BRIEF DESCRIPTION OF THE DRAWINGS

Various ones of the appended drawings merely illustrate example embodiments of the present disclosure and should not be considered as limiting its scope.

FIG. 1 illustrates example portions of a wi-fi sensing system.

FIG. 2 illustrates example portions of a receiver/sniffer device.

FIG. 3 illustrates example portions of an integrated receiver/sniffer device.

FIG. 4 illustrates a network topology of a wi-fi sensing system.

FIG. 5 illustrates a flow diagram for a method of transmitting CSI frames.

FIG. 6 illustrates a flow diagram for a method to update configurations of a device.

FIG. 7 illustrates a flow diagram for a method to update configurations of a device.

### DETAILED DESCRIPTION

Wi-fi sensing systems and techniques using receiving devices with two radio chains are described herein. The receiving devices may utilize the first radio chain to receive messages from a transmitter in a first wireless communication network and may generate environment characterization information based on those received messages. The receiving devices may utilize the second radio chain to transmit the environment characterization information to a host device using a second wireless communication network.

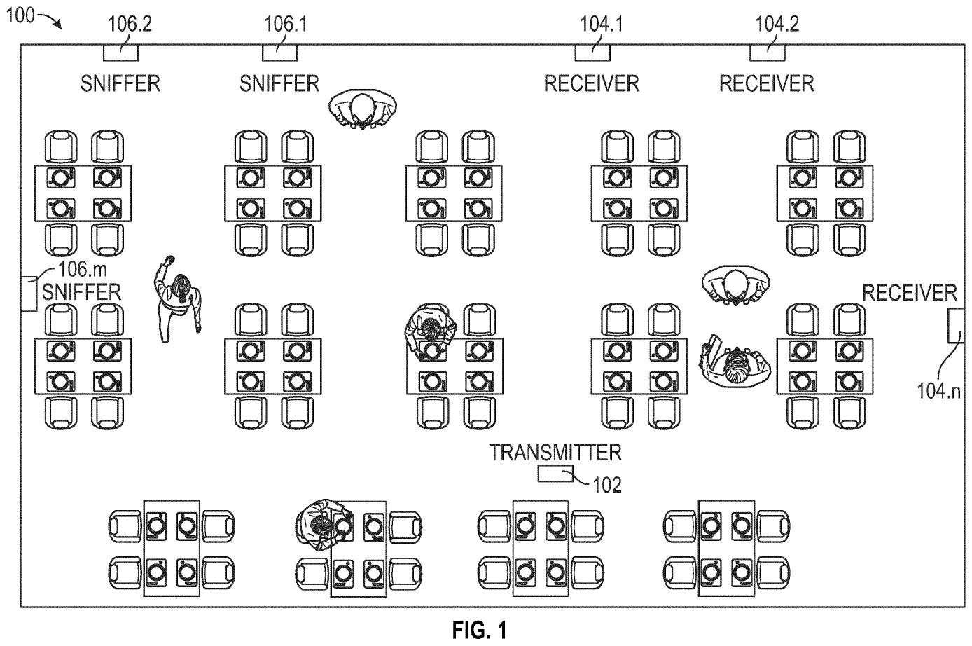

FIG. 1 illustrates example portions of a wi-fi sensing system 100. In FIG. 1, the wi-fi sensing system 100 is illustrated as being deployed in a cafeteria for illustration purposes only, and the wi-fi sensing system 100 can be deployed in other environments, as described in further detail below. Other example environments can include conference rooms, hospitals, airports, classrooms, or any other suitable environment.

The wi-fi sensing system 100 may include a transmitter 102, a plurality of receivers 104.1-104.n, and a plurality of sniffers 106.1-106.m. The transmitter 102 may transmit messages that can be used by the plurality of receivers 104.1-104.n and sniffers 106.1-106.m to characterize the environment where the wi-fi sensing system 100 is deployed, which in this example is a cafeteria. The messages may be transmitted on one or more channels of a wi-fi wireless communication network, for example, as defined by the IEEE 802.11 standard. For example, the transmitter 102 may transmit the messages on a specified channel in the 2.4 GHz, 5 GHz, or 6 GHz band. Other communication protocols may also be used. The content of the messages may be fixed, such as a constant word (e.g., hello) or number, or may be variable, which can be changed by the transmitter 102.

The plurality of receivers 104.1-104.n may be paired with or connected to the transmitter 102 based on the appropriate communication protocol, and therefore the transmitter 102 may have stored information about the plurality of receivers 104.1-104.n. For example, the transmitter 102 may expose its Service Set Identifier (SSID) to the plurality of receivers 104.1-104.n, and the plurality of receivers 104.1-104.n may connect to the transmitter using the SSID. After a receiver connects to the transmitter 102, the receiver's information (such as MAC address) may be stored in the transmitter 102.

The plurality of receivers 104.1-104.n may receive the messages transmitted by the transmitter 102 and may generate channel state information (CSI) frames based on the received messages. For example, the CSI frames generated by a receiver (say receiver 104.2) of the plurality of receivers 104.1-104.n may include amplitude and phase information of a particular subcarrier that was used to transmit the message to that respective receiver. The CSI can be used to characterize the environment of the wi-fi sensing system 100, as described in further detail below.

An antenna associated with the transmitter 102 may include a specified number of subcarriers, e.g., thirty subcarriers. As mentioned above, the plurality of receivers 104.1-104.n may be paired with or connected to the transmitter 102, and therefore the transmitter 102 may send messages directed to respective receivers. For example, the transmitter 102 can direct messages to any respective receiver (say, receiver 104.1) of the plurality of receivers 104.1.104.n.

As explained in further detail below, the plurality of sniffers 106.1-106.m may be provided using the same or similar hardware architecture as the plurality of receivers 104.1-104.m. Unlike the plurality of receivers 104.1-104.n, the plurality of sniffers 106.1-106.m may not be paired with or connected to the transmitter 102 based on the appropriate communication protocol. The transmitter 102 may not have stored information about the plurality of sniffers 106.1-106m. That is, the transmitter 102 may not be able to direct messages to the plurality of sniffers 106.1-106.m. Moreover, while the number of receivers (n) may be set based on restrictions on how many devices can be simultaneously connected to the transmitter 102, the number of sniffers (m) is not impacted by those same restrictions. Therefore, in some examples, the number of sniffers (m) may be greater than the number of receivers (n).

The plurality of sniffers 106.1-106.m may scan or “sniff” a specified frequency spectrum and intercept or receive messages transmitted by the transmitter 102 in that spectrum. Based on those “sniffed” messages, the plurality of sniffers 106.1-106.m may generate CSI frames, and the CSI frames may include amplitude and phase information per subcarrier.

The CSI frames generated by the plurality of receivers 104.1-104.m and plurality of sniffers 106.1-106.m may then be collected and used to characterize the relevant environment. For example, the CSI frames can be used to detect changes in the environment using pattern recognition techniques for a variety of applications such as counting the number people, detecting movement, poses, and gestures, etc. Since wi-fi sensing uses electromagnetic (EM) waves, the information extracted from the change in patterns can be more robust than to other detection techniques such as cameras. While cameras capture information directly in the line of sight of its camera sensor, wi-fi sensing can detect objects and movement outside the line of sight of the devices (transmitter and receiving devices). That is because EM waves can reflect off objects outside the line of sight between two devices and those reflected EM waves can then be received by the receiving device. A change in that object outside of the line of sight can therefore impact the CSI.

However, as mentioned above, conventional techniques for collecting CSI frames to perform the data analysis for pattern recognition can be lacking. For instance, if the plurality of receivers 104.1-104.n and sniffers 106.1-106.m transmit the CSI frames back to the transmitter 102 using the same wireless communication network used to measure the CSI, those transmissions can cause interference that can impact the CSI measurements. Thus, the transmission of the CSI frames may interfere with the CSI measurements. Using wired connections for the plurality of receivers 104.1-104n and sniffers 106.1-106.m also comes with drawbacks including wiring cost, complexity, and space limitations.

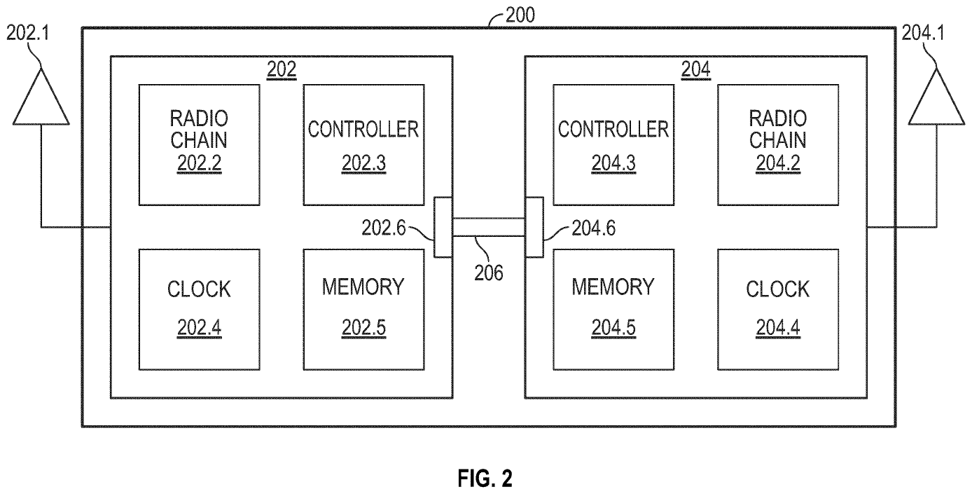

Hence, as described herein, examples of receiver/sniffer devices are described, which can transmit the CSI frames using a different wireless communication network than the wireless communication network used to generate the CSI frames in a low-cost and efficient manner without causing interference with the CSI measurements. FIG. 2 shows example portions of a receiver/sniffer device 200. The receiver/sniffer device 200 can be used as either a receiver or sniffer in wi-fi sensing systems as described herein (e.g., wi-fi sensing system 100).

The receiver/sniffer device 200 may include a wi-fi sensing module 202 and a buddy module 204 coupled by a bus 206. The wi-fi sensing module 202 may include an antenna 202.1, a radio chain 202.2, a controller 202.3, a clock 202.4, a memory 202.5, and a bus interface 202.6. In some examples, the wi-fi sensing module 202 may be provided as an integrated circuit, such as a System on Chip (SoC) device, may be low cost and may have a small form factor. The antenna 202.1 may be tuned to receive messages in a specified bandwidth (e.g., 2.4 GHz, 5 GHz, or 6 GHz). The radio chain 202.2 may include Radio Frequency (RF) components such as RF baluns, amplifiers, downconverters, etc. to receive messages in the RF spectrum and convert received messages to baseband signals for CSI measurements. The controller 202.3 may be provided as a microprocessor with single or multiple cores. As described in further detail below, the controller 202.3 may generate CSI frames based on the received messages. The clock 202.4 may include an oscillator and may generate clock signals at specified frequencies to be used by the other components in the wi-fi sensing module 202. The memory 202.5 may include read-only memory (ROM), random access memory (RAM), static random-access memory (SRAM), flash memory, and/or other suitable memory components. As described in further detail below, the memory 202.5 may store CSI frames, configuration information such as firmware, and other programs used by the wi-fi sensing module 202.

The wi-fi sensing module 202 may be configured to receive messages from a first wireless communication network (say, from transmitter 102) and may generate CSI frames based on received messages from the first wireless communication network, as described above. The wi-fi sensing module 202 may transmit the CSI frames to the buddy module 204 via the bus 206. The bus interface 202.6 may be provided as a low-level bus interface, such as Serial Peripheral Interface (SPI), Inter-Integrated Circuit (I2C), Universal Asynchronous receiver/transmitter (UART), Controller Area Network (CAN), etc.

The buddy module 204 may include an antenna 204.1, a radio chain 204.2, a controller 204.3, a clock 204.4, a memory 204.5, and a bus interface 204.6. In some examples, the buddy module 204 may be provided as an integrated circuit, such as a low cost and small form factor SoC device. The antenna 204.1 may be tuned to transmit and receive messages in a specified bandwidth. The radio chain 204.2 may include RF components such as RF baluns, amplifiers, upconverters, downconverters, etc., to transmit and receive RF signals. The controller 204.3 may be provided as a microprocessor with single or multiple cores. As described in further detail below, the controller 204.3 may process the received CSI frames (e.g., filtering, compressing) and may add metadata to the CSI frames to be transmitted. The clock 204.4 may include an oscillator and may generate clock signals at specified frequencies to be used by the other components in the buddy module 204. The memory 204.5 may include ROM, RAM, SRAM, flash memory, and/or other suitable memory components. The bus interface 202.6 may be provided as a low-level bus interface, SPI, I2C, UART, CAN, etc. to communicate with the wi-fi sensing module 202 over the bus 206.

The buddy module 204 may receive the CSI frames from the wi-fi sensing module 202 over the bus 206 and may transmit the CSI frames via its antenna 204.1 and radio chain 204.2 to a host device or router using a second wireless communication network, which is different from the first wireless communication network used by the wi-fi sensing module 202 for generating CSI frames. The second wireless communication network used by the buddy module 202 may be provided as another wi-fi network, a Bluetooth network, a Zigbee network, or other wireless network using any other suitable wireless network protocol(s).

The channel(s) used by the second wireless communication network may be set so that those channel(s) are sufficiently distanced from the channel(s) used in the first wireless communication network to not significantly interfere with the CSI measurements in the first wireless communication network. In some examples, if the second wireless communication network is provided as another wi-fi network, the channel used by the second wireless communication network may be set to a channel that is at least ten channels apart from the channel used by the first wireless communication network. For instance, if the first wireless communication network is using channel 1 for CSI measurements, the second wireless communication network may be set to channel 11 or higher.

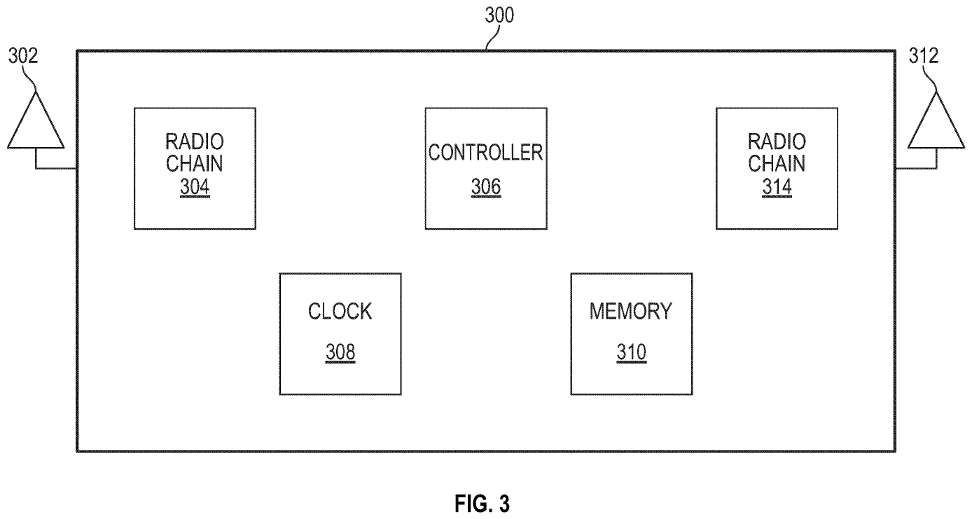

While receiver/sniffer device 200 of FIG. 2 includes separate, discreet wi-fi sensing and buddy modules (202, 204), these modules can also be integrated together in other examples. FIG. 3 shows example portions of an integrated receiver/sniffer device 300. The integrated receiver/sniffer device 300 can be used as either a receiver or sniffer in wi-fi sensing systems described herein.

The integrated receiver/sniffer device 300 may include a first antenna 302, a first radio chain 304, a controller 306, a clock 308, a memory 310, a second antenna 312, and a second radio chain 314. In some examples, the integrated receiver/sniffer device 300 may be provided as an integrated circuit, such as a low cost and small form factor SoC device. The first antenna 302 may be tuned to receive messages in a specified bandwidth associated with the first wireless communication network used for CSI frame generation. The first radio chain 306 may include RF components such as RF baluns, amplifiers, downconverters, etc., to receive messages in the RF spectrum and convert the received messages to baseband signals for CSI measurements. The controller 306 may be provided as a microprocessor with single or multiple cores. The clock 308 may include an oscillator and may generate clock signals at specified frequencies to be used by the other components in the integrated receiver/sniffer device 300. The memory 308 may include ROM, RAM, SRAM, flash memory, and/or other suitable memory components.

The second antenna 312 may be tuned to transmit and receive messages in a specified bandwidth associated with the second wireless communication network. The second radio chain 204.2 may include RF components such as RF baluns, amplifiers, upconverters, downconverters, etc. to transmit and receive RF signals.

The integrated receiver/sniffer device 300 may receive messages transmitted from a first wireless communication network using the first antenna 302 and first radio chain 304 and may generate CSI frames based on those received messages. The integrated receiver/sniffer device 300 may then transmit the CSI frames using a second wireless communication network via the second antenna 312 and second radio chain 314.

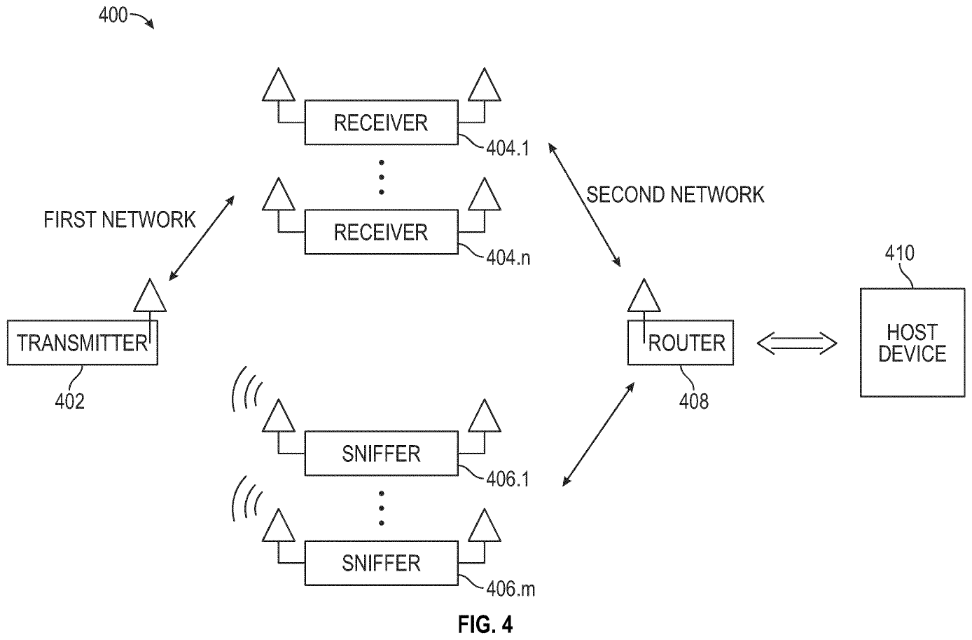

FIG. 4 illustrates a network topology of a wi-fi sensing system 400. The wi-fi sensing system 400 may include a transmitter 402, a plurality of receivers 404.1-404.n, a plurality of sniffers 406.1-406.m, a router 408, and a host device 410. The transmitter 402 may transmit messages using a first wireless communication network that can be used by the plurality of receivers 404.1-404.n and sniffers 406.1-406.m for CSI frame generation to characterize the environment where the wi-fi sensing system 400 is deployed, as descried above. The first wireless communication network may be provided as a wi-fi network.

The receivers 404.1-404.n and sniffers 406.1-406.m may include hardware architecture as described herein (e.g., receiver/sniffer 200, integrated receiver/sniffer 300). The receivers 404.1-404.n may be paired with or connected to the transmitter 400 while the sniffers 406.1-406.m may scan or sniff the relevant frequency spectrum for the messages from the transmitter 400, as described above. The receivers 404.1-404.n and sniffers 406.1-406.m may receive and sniff the messages from the transmitter 402 and generate CSI frames based on those messages. The receivers 404.1-404.n and sniffers 406.1-406.m may then transmit CSI frames to the router 408 using a second wireless communication network. The second wireless communication network may be provided as another wi-fi network, a Bluetooth network, a Zigbee network, or other wireless network using any other suitable wireless network protocol(s), as described herein.

The router 408 may be coupled to the host device 410. The router 408 and the host device 410 may be provided locally in some examples. In some examples, the router 408 and host device 410 may be integrated together. In other examples, the host device 410 may be located in a remote location such as a cloud computing platform and the router 408 and the host device may be communicatively coupled together via, for example, the internet.

The host device 410 may collect the CSI frames received from the receivers 404.1-404.n and sniffers 406.1-406.m and may utilize patent recognition techniques such as complex machine learning networks to identify patterns to characterize the environment of the wi-fi sensing system 400. For example, the host device 410 may include one or more processor circuits, such as a computer processing unit (CPU), a graphic processing unit (GPU), a field programmable gate array (FPGA). The CPU may be provided as one or more multi-core processors. The GPU and FPGA may be used to accelerate the processing of the CSI and the performance of the machine learning network. The machine learning network may be provided as a multi-layered machine learning model, a neural network, or other suitable networks.

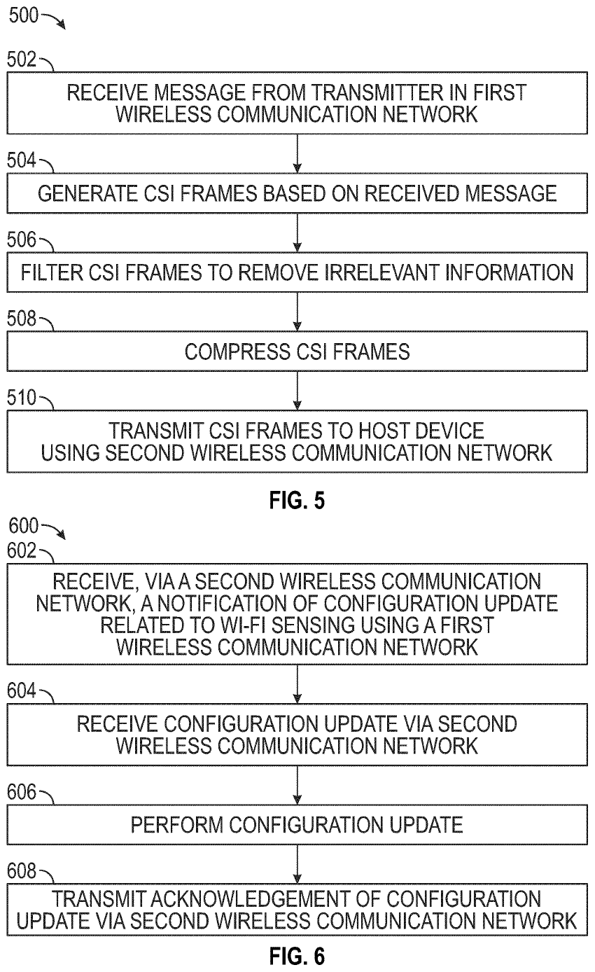

FIG. 5 illustrates a flow diagram for a method 500 of transmitting CSI frames. In some examples, the method 500 may be executed by a receiver or sniffer device as described herein (e.g., receiver/sniffer 200, integrated receiver/sniffer 300). At operation 502, messages from a transmitter may be received by the receiver/sniffer device using a first wireless communication network, e.g., a wi-fi network. At operation 504, CSI frames may be generated based on the received messages. For example, the CSI frames may include amplitude and phase information of a particular subcarrier that was used to transmit a respective message.

At operation 506, the CSI frames may be filtered to remove data that do not carry relevant information. At operation 508, the filtered CSI frames may be compressed. For example, data reducing algorithms may be executed on the receiver/sniffer device (e.g., buddy module) to reduce the amount of data in the generated CSI frames to be transmitted to the host device. The data reducing algorithms may include compression algorithms, performing dimension reduction, fitting the data on a curve and only transmitting the parameters of the curve to be used, etc.

In some examples, Huffman encoding may be used to reduce the amount of CSI data to be transmitted from the receiver/sniffer device. Since CSI frames usually exhibit linear variation between adjacent channels, Huffman encoding compression can be further optimized by considering delta between each channel value instead of the original channel value. For example, CSI frames for channels may follow the pattern of 0, 5, 10, 15, 10, 5, 0, −5, −10 . . .

Corresponding delta series would be 0, +5, +5, +5,-5, −5, −5, −5, −5 . . . Thus, associated Huffman encoding dictionary would be only consisting solely of 0, +5, −5 instead of 0, 5, 10, 15, −5, −10. Therefore, the receiver/sniffer device may not transmit the actual CSI frames, but instead may transmit the Huffman encoding of difference between adjacent channels. This can reduce sensibly the amount of data to be transmitted.

At operation 510, the compressed CSI frames may be transmitted to the host device using a second wireless communication network. In addition, metadata may be added to the CSI frames (e.g., by the buddy module). The metadata may include timestamp information, receiver/sniffer identification information, and other information.

The second wireless communication network may be provided as another wi-fi network, a Bluetooth network, a Zigbee network, or other wireless network using any other suitable wireless network protocol(s), as described herein. The host device may collect the CSI frames received from a plurality receivers and sniffers placed at different locations in the environment to be characterized. The host device may utilize patent recognition techniques such as using machine learning networks to identify patterns to characterize the environment for a variety of applications such as counting the number people, detecting movement and gestures, etc.

In addition to the transportation of CSI frames, the communication techniques described herein can be used for other applications. Configuration and firmware updates on the receiver/sniffer devices may be executed using two different wireless communication networks. FIG. 6 illustrates a flow diagram for a method 600 to update configurations of a device. In some examples, the method 600 may be performed by a receiver or sniffer device as described herein (e.g., receiver/sniffer 200, integrated receiver/sniffer 300).

At operation 602, the receiver/sniffer device may receive a notification regarding a configuration update for the wi-fi sensing components via the second wireless communication network, which is different from the first wireless communication network used for CSI generation, as described above. In the examples in which the buddy and wi-fi sensing modules are provided as separate, discreet modules (e.g., receiver/sniffer 200), the buddy module may receive the notification via the second wireless communication network and transmit information regarding the notification to the wi-fi sensing module via the wired bus.

At operation 604, the receiver/sniffer device may receive the configuration update for the wi-fi sensing components via the second wireless communication network. In the examples in which the buddy and wi-fi sensing modules are provided as separate, discreet modules (e.g., receiver/sniffer 200), the buddy module may receive the configuration via the second wireless communication network and transmit information regarding the configuration update to the wi-fi sensing module via the wired bus.

In some examples, the configuration update may include firmware updates related to wi-fi sensing components. In some examples, the configuration update may include communication parameters (e.g., channel, modulation, etc.) used by the first wireless communication network for generating CSI.

At operation 606, the receiver/sniffer device may perform the configuration update. At operation 608, the receiver/sniffer device may transmit an acknowledgement that the configuration update has been executed via the second wireless communication network. In the examples in which the buddy and wi-fi sensing modules are provided as separate, discreet modules (e.g., receiver/sniffer 200), the wi-fi sensing module may perform the configuration update and may transmit information regarding the completion of the configuration update to the buddy module via the wired bus. In turn, the buddy module may transmit the acknowledgement that the configuration update has been executed via the second wireless communication network.

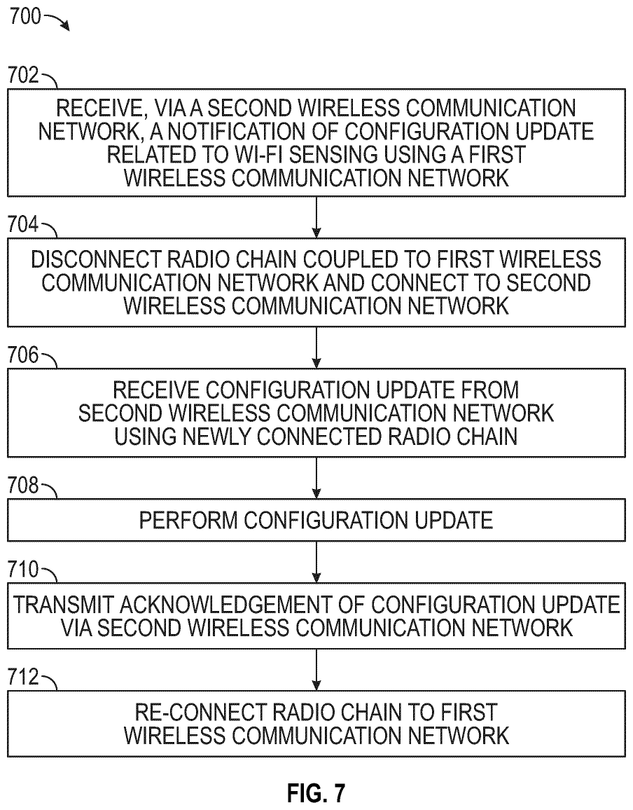

Other techniques may also be used for configuration updates. FIG. 7 illustrates a flow diagram for a method 700 to update configurations of a device. In some examples, the method 700 may be performed by a receiver or sniffer device as described herein (e.g., receiver/sniffer 200, integrated receiver/sniffer 300).

At operation 702, the receiver/sniffer device may receive a notification regarding a configuration update for the wi-fi sensing components via the second wireless communication network, which is different from the first wireless communication network used for CSI generation, as described above. In the examples in which the buddy and wi-fi sensing modules are provided as separate, discreet modules (e.g., receiver/sniffer 200), the buddy module may receive the notification via the second wireless communication network and transmit information regarding the notification to the wi-fi sensing module via the wired bus.

At operation 704, the receiver/sniffer device may disconnect the radio chain (e.g., radio chain 202.2, radio chain 304) coupled to the first wireless communication network used for CSI generation and connect that radio chain to the router in the second wireless communication network. In the examples in which the buddy and wi-fi sensing modules are provided as separate, discreet modules (e.g., receiver/sniffer 200), the radio chain in the wi-fi sensing module may switch from its connection or sniffing configuration of the first wireless communication network and may connect to the router in the second wireless communication network.

At operation 706, the receiver/sniffer device may receive the receive the configuration update for the wi-fi sensing components from the second wireless communication network via the radio chain (e.g., radio chain 202.2, radio chain 304) that was previously connected to the first wireless communication network but not connected to the second wireless communication network. In the examples in which the buddy and wi-fi sensing modules are provided as separate, discreet modules (e.g., receiver/sniffer 200), the radio chain in the wi-fi sensing module may receive the configuration update from the router in the second wireless communication network.

At operation 708, the receiver/sniffer device may perform the configuration update. At operation 710, the receiver/sniffer device may transmit an acknowledgement that the configuration update has been executed to the second wireless communication network via the radio chain (e.g., radio chain 202.2, radio chain 304) that was previously connected to the first wireless communication network but now connected to the second wireless communication network. In the examples in which the buddy and wi-fi sensing modules are provided as separate, discreet modules (e.g., receiver/sniffer 200), the radio chain in the wi-fi sensing module may transmit the acknowledgement to the router in the second wireless communication network.

At operation 712, the receiver/sniffer device may re-connect the radio chain (e.g., radio chain 202.2, radio chain 304) that was previously disconnected at operation 704 to the first wireless communication network used for CSI generation but now with the executed configuration update. In the examples in which the buddy and wi-fi sensing modules are provided as separate, discreet modules (e.g., receiver/sniffer 200), the radio chain in the wi-fi sensing module may switch its connection or sniffing configuration back to the first wireless communication network with the executed configuration update.

In the examples described above, components were described and illustrated as singe input singe output (SISO) devices for simplicity and brevity. Other types of devices can be used for the communication techniques described herein, such as multiple input single output (MISO) and/or multiple input multiple output (MIMO) devices.

The CSI generation and communication techniques described herein can utilize low-cost, small form factor, embedded devices. The use of such devices can facilitate scalability leading to the design and use of large wi-fi sensing systems using tens or hundreds of receiving and sniffing devices.

### Various Notes

Each of the non-limiting examples above can stand on its own or can be combined in various permutations or combinations with one or more of the other aspects or other subject matter described in this document.

The above detailed description includes references to the accompanying drawings, which form a part of the detailed description. The drawings show, by way of illustration, specific implementations in which the invention can be practiced. These implementations are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in a aspects are still deemed to fall within the scope of that aspect. Moreover, in the following aspects, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to allow the reader to quickly ascertain the nature of the technical disclosure.

1. A device for wi-fi sensing, comprising:
a first radio chain to receive messages from a transmitter associated with a first wireless communication network, wherein the device to generate channel state information (CSI) frames based on the received messages; and
a second radio chain to transmit the CSI frames to a host device using a second wireless communication network.

2. The device of claim 1, wherein the first radio chain is provided in a first module and the second radio chain is provided in a second module, wherein the first and second modules are connected by a wired bus.

3. The device of claim 2, wherein the first module includes a first controller to generate the CSI frames and the second module includes a second controller to add metadata to the CSI frames.

4. The device of claim 2, wherein the wired bus is a Serial Peripheral Interface (SPI), Inter-Integrated Circuit (I2C), Universal Asynchronous receiver/transmitter (UART), or Controller Area Network (CAN).

5. The device of claim 1, wherein the first wireless communication network is a wi-fi network.

6. The device of claim 5, wherein the first wireless communication network is configured to operate on a first channel, wherein the second wireless communication network is a different wi-fi network configured to operate on a second channel that is at least ten channels apart from the first channel.

7. The device of claim 5, wherein the second wireless communication network is a Zigbee network.

8. The device of claim 1, further comprising:
a controller to compress the CSI frames.

9. The device of claim 8, wherein the controller uses Huffman encoding of adjacent channels difference to compress the CSI frames.

10. The device of claim 1, wherein the second radio chain is configured to receive a notification regarding a configuration update relating to the first radio chain.

11. The device of claim 1, the first radio chain is configured to disconnect from the first wireless communication network and to connect to the second wireless communication network to receive a configuration update.

12. A method for wi-fi sensing, the method comprising:
receiving messages from a transmitter associated with a first wireless communication network;
generating channel state information (CSI) frames based on the received messages; and
transmitting the CSI frames to a host device using a second wireless communication network.

13. The method of claim 12, wherein the messages are received and the CSI frames are generated in a first module, the method further comprising:
transmitting the CSI frames from the first module to a second module via a wired bus, wherein the CSI frames are transmitted to the host device using the second module.

14. The method of claim 12, further comprising:
adding metadata to the CSI frames.

15. The method of claim 12, wherein the first wireless communication network is a wi-fi network operating on a first channel and the second wireless communication network is a different wi-fi network operating on a second channel that is at least ten channels apart from the first channel.

16. The method of claim 12, further comprising:
compressing the CSI frames.

17. The method of claim 16, wherein the compressing is performed using Huffman encoding of adjacent channels difference.

18. The method of claim 12, further comprising:
receiving, via the second wireless communication network, a notification regarding a configuration update relating to components used for communicating with the first wireless communication network.

19. The method of claim 18, further comprising:
disconnecting a radio chain used to receive the messages from the first wireless communication network;
connecting the radio chain to the second wireless communication network;
receiving, via the radio chain connected to the second wireless communication network, configuration update related to the first wireless communication network;
re-connecting the radio chain to the first wireless communication network with the configuration update.

20. A wi-fi sensing system comprising:
a transmitter to transmit messages;
a host device; and
a receiver to receive the messages from the transmitter using a first wireless communication network, to generate channel state information (CSI) frames based on the received messages, and to transmit the CSI frames to the host device using a second wireless communication network.

21. The wi-fi sensing system of claim 20, further comprising:
a sniffer to scan for the messages from the transmitter using the first wireless communication network, to generate sniffer CSI frames based on the scanned messages, and to transmit the sniffer CSI frames using the second wireless communication network.
